(19) United States
(12) Patent Application Publication
(10) Pub. No.: US 2020/0333820 A1
(43) Pub. Date: Oct. 22, 2020

(54) CONSTANT CURRENT CIRCUIT AND SEMICONDUCTOR DEVICE

(71) Applicant: ABLIC Inc., Chiba-shi (JP)

(72) Inventors: Tomoki HIKICHI, Chiba-shi (JP); Kentaro Fukai, Chiba-shi (JP); Takaaki Hioka, Chiba-shi (JP); Yohei Ogawa, Chiba-shi (JP)

(21) Appl. No.: 16/838,492

(22) Filed: Apr. 2, 2020

(30) Foreign Application Priority Data
Apr. 17, 2019 (JP) 2019-078441

(51) Int. Cl. G05F 3/24; G05F 1/56; H01L 21/8236; H01L 27/02; H03K 19/003

(52) U.S. Cl. CPC G05F 3/24; G05F 1/56; H03K 19/00315; H01L 27/02; H01L 21/8236

(57) ABSTRACT

A constant current circuit includes a depletion-type NMOS transistor having a drain connected to a constant current output terminal, and a resistance element provided between the depletion-type NMOS transistor and a ground terminal. The depletion-type NMOS transistor includes a first depletion-type NMOS transistor and a second depletion-type NMOS transistor which are connected in parallel and arranged to have current directions forming an angle of 90 degrees. The resistance element includes a first resistor and a second resistor which are arranged to have current directions forming an angle of 90 degrees.

### RELATED APPLICATIONS

This application claims priority to Japanese Patent Application No. 2019-078441, filed on Apr. 17, 2019, the entire content of which is incorporated herein by reference.

### BACKGROUND OF THE INVENTION

### 1. Field of the Invention

The present invention relates to a constant current circuit and a semiconductor device including the constant current circuit.

### 2. Description of the Related Art

Hitherto, there have been known a constant current circuit which includes a depletion-type MOS transistor and a resistor connected in series, and which can supply a stable constant current even if the threshold value of the MOS transistor varies during a manufacturing process (see, for example, Japanese Patent Application Laid-open No. H 11-194844).

However, in the related-art constant current circuit, regarding fluctuation in characteristics of the MOS transistor during the manufacturing process, precision of the current is controlled, but regarding drift of characteristics including the precision of the current and the like caused by stress applied at the time of sealing into a resin package consideration is not made.

### SUMMARY OF THE INVENTION

It is an object of the present invention to provide a constant current circuit in which precision of the constant current can be controlled against stress applied at the time sealing into a resin package.

A constant current circuit according to an embodiment of the present invention includes: a depletion-type NMOS transistor having a drain connected to a constant current output terminal; and a resistance element provided between the depletion-type NMOS transistor and a ground terminal. The depletion-type NMOS transistor includes a first depletion-type NMOS transistor and a second depletion-type NMOS transistor which are connected in parallel and arranged to have current directions forming an angle of 90 degrees, and the resistance element includes a first resistor and a second resistor which are arranged to have current directions forming an angle of 90 degrees.

The constant current circuit according to the present invention is formed of the two depletion-type NMOS transistors connected in parallel and arranged to have the current directions that form an angle of 90 degrees. Accordingly, it is possible to easily control the constant current against the stress applied at the time of sealing into the resin package.

### BRIEF DESCRIPTION OF THE DRAWINGS

FIG. 1 is a circuit diagram illustrating an example of a constant current circuit according to an embodiment of the present invention.

FIG. 2 is a circuit diagram illustrating another example of the constant current circuit according to the embodiment of the present invention.

FIG. 3 is a circuit diagram illustrating another example of the constant current circuit according to the embodiment of the present invention.

FIG. 4 is a circuit diagram illustrating another example of the constant current circuit according to the embodiment of the present invention.

FIG. 5 shows a semiconductor device having one of constant current circuits explained as examples of the embodiment.

### DETAILED DESCRIPTION OF THE PREFERRED EMBODIMENTS

Now, a description is made of an embodiment of the present invention with reference to the drawings.

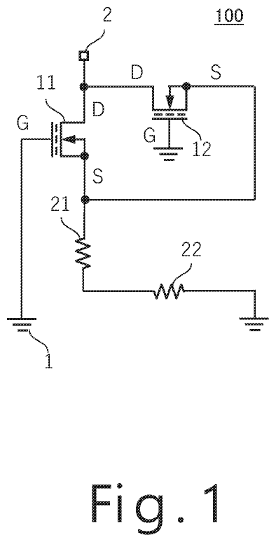

FIG. 1 is a circuit diagram illustrating an example of a constant current circuit according to the embodiment of the present invention.

The constant current circuit 100 includes a depletion-type NMOS transistor 11 (abbreviated as NMOS transistor 11), a depletion-type NMOS transistor 12 (abbreviated as NMOS transistor 12), a resistor 21, and a resistor 22.

The NMOS transistor 11 and the NMOS transistor 12 each have a drain D connected to a current output terminal 2, a gate G connected to a ground terminal 1, and a source S connected to one end of the resistor 21. That is, the NMOS transistor 11 and the NMOS transistor 12 are electrically connected in parallel. The resistor 22 has one end connected to the other end of the resistor 21 and has the other end connected to the ground terminal 1.

The NMOS transistor 11 and the NMOS transistor 12 are arranged on a semiconductor substrate so that directions of current flowing through each of the NMOS transistors 11 and 12, that is, drain-to-source directions of each of the NMOS transistors 11 and 12 form an angle of 90 degrees. Likewise, the resistor 21 and the resistor 22 are arranged so that directions of current flowing through each of the resistors 21 and 22 form an angle of 90 degrees. Here, the direction of current flowing through each of the NMOS transistor 11 and the resistor 21 is referred to as “x direction (first direction),” and the direction of current flowing through each of the NMOS transistor 12 and the resistor 22 is referred to as “y direction (second direction).”

With regard to the thus-configured constant current circuit 100, a description is made of variation in characteristics against stress applied at the time of sealing into a resin package.

In a semiconductor chip sealed into the resin package, provided that the chip surface is defined as x-y plane, the stress applied to the center portion of the chip is expressed by the sum of x-component stress σₓₓ and y-component stress σ_{yy}: σₓₓ+σ_{yy} (isotropic stress). The amount of drift is mainly determined by π (σₓₓ+σ_{yy}) which is obtained by multiplying the sum (σₓₓ+σ_{yy}) with a piezoelectric coefficient π specific to the element forming the circuit, and which changes the characteristics of the circuit.

Strictly speaking, examination of the piezoelectric coefficient π is necessary to decompose into π_{∥} for the case the current direction is parallel to the stress vector and π_{⊥} for the case the current direction is perpendicular to the stress vector.

Since the direction of current flowing through the NMOS transistor 11 and the resistor 21 is in the x direction, the main drift amount is expressed by π_{∥}σₓₓ+π_{⊥}σ_{yy}. Besides, since the direction of current flowing through the NMOS transistor 12 and the resistor 22 is the y direction, the main drift amount is expressed by π_{⊥}σₓₓ+π_{∥}σ_{yy}.

Consequently, the main drift amount of the characteristics of the NMOS transistor 11 and the NMOS transistor 12, and the resistor 21 and the resistor 22 is expressed by (π_{∥}+π_{⊥})(σₓₓ+σ_{yy}), resulting in an expression proportional to the isotropic stress.

As described above, in the constant current circuit 100, the NMOS transistor 11 and the NMOS transistor 12 are arranged orthogonal to each other to form 90 degrees, and the resistor 21 and the resistor 22 are arranged orthogonal to each other to form 90 degrees, and hence when the x-component stress σₓₓ and the y-component stress σ_{yy} independently vary, the main drift amount is kept constant unless the sum thereof varies. For this reason, a benefit is obtained in which a stress response operation can easily be estimated.

As described above, since the transistors and the resistors as components thereof are arranged orthogonal to each other to form 90 degrees in the constant current circuit 100, it is possible to supply a constant current proportional to the isotropic stress.

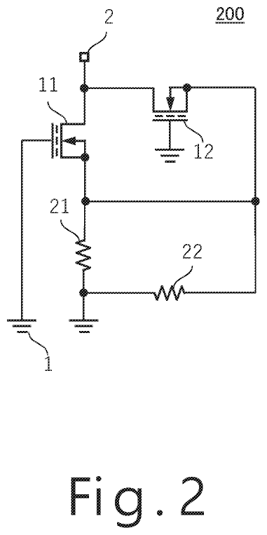

FIG. 2 is a circuit diagram illustrating another example of the constant current circuit according to the embodiment of the present invention.

A constant current circuit 200 includes a depletion-type NMOS transistor 11, a depletion-type NMOS transistor 12, a resistor 21, and a resistor 22.

The difference from the constant current circuit 100 is that the resistor 21 and the resistor 22 are electrically connected in parallel. That is, the parallel-connected NMOS transistor 11 and NMOS transistor 12 are arranged orthogonal to form an angle of 90 degrees, and the parallel-connected resistor 21 and resistor 22 are arranged orthogonal to form an angle of 90 degrees.

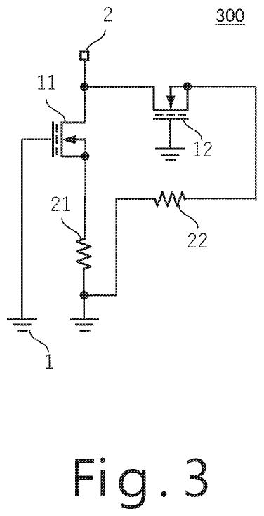

FIG. 3 is a circuit diagram illustrating another example of the constant current circuit according to the embodiment of the present invention.

A constant current circuit 300 includes a depletion-type NMOS transistor 11, a depletion-type NMOS transistor 12, a resistor 21, and a resistor 22.

The difference from the constant current circuit 200 is that the NMOS transistor 11 and the resistor 21 are connected in series, and the NMOS transistor 12 and the resistor 22 are connected in series. That is, the NMOS transistor 11 and the resistor 21 that are connected in series and have the same current direction in x-direction are arranged orthogonal to the NMOS transistor 12 and the resistor 22 that are connected in series and have the same current direction in y-direction to form an angle of 90 degrees.

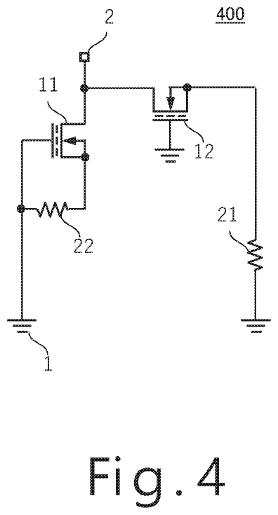

FIG. 4 is a circuit diagram illustrating another example of the constant current circuit according to the embodiment of the present invention.

A constant current circuit 400 includes a depletion-type NMOS transistor 11, a depletion-type NMOS transistor 12, a resistor 21, and a resistor 22.

The difference from the constant current circuit 300 is that the NMOS transistor and the resistor are connected in series and arranged orthogonal so that the current flowing through the NMOS transistor and the current flowing through the resistor form an angle of 90 degrees.

The constant current circuits 200, 300, and 400 illustrated in FIG. 2, FIG. 3, and FIG. 4, respectively, can produce the same effect as in the constant current circuit 100 of FIG. 1.

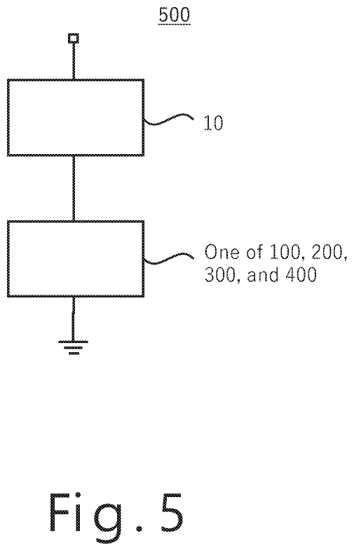

FIG. 5 shows a semiconductor device having one of the constant current circuits (100, 200, 300, and 400) explained above as the examples of the embodiment. The constant current circuit is connected to a functional circuit 10 which is driven by the constant current provided from the constant current circuit.

The embodiments of the present invention have been described above, but the present invention is not limited to the above-mentioned embodiment, and it is understood that various modifications can be made thereto without departing from the gist of the present invention.

For example, in the above-mentioned example, the gate of the depletion-type transistor is grounded but may be connected to a reference voltage higher than the threshold value VTH.

The constant current circuit of the present invention can be preferably applied to, for example, a semiconductor (sensor) device including a Hall element. A drift amount of main characteristic of the Hall element is determined in proportion to the isotropic stress. Accordingly, the constant current circuit of the present invention is worth in correcting the drift of the main characteristic of the Hall element caused at the time of sealing into the resin package.

What is claimed is:

1. A constant current circuit, comprising:
a depletion-type NMOS transistor having a drain connected to a constant current output terminal; and
a resistance element provided between the depletion-type NMOS transistor and a ground terminal,
the depletion-type NMOS transistor comprising a first depletion-type NMOS transistor and a second depletion-type NMOS transistor which are connected in parallel and arranged to have current directions forming an angle of 90 degrees,
the resistance element comprising a first resistor and a second resistor which are arranged to have current directions forming an angle of 90 degrees.

2. The constant current circuit according to claim 1, wherein the first resistor and the second resistor are connected in series between the ground terminal and a source of each of the first depletion-type NMOS transistor and the second depletion-type NMOS transistor.

3. The constant current circuit according to claim 1, wherein the first resistor and the second resistor are connected in parallel between the ground terminal and a source of each of the first depletion-type NMOS transistor and the second depletion-type NMOS transistor.

4. A constant current circuit, comprising:
a depletion-type NMOS transistor having a drain connected to a constant current output terminal; and
a resistance element provided between the depletion-type NMOS transistor and a ground terminal,
the depletion-type NMOS transistor comprising a first depletion-type NMOS transistor and a second depletion-type NMOS transistor that have gates connected in common, and are arranged to have current directions forming an angle of 90 degrees,
the resistance element comprising a first resistor and a second resistor that are arranged to have current directions forming an angle of 90 degrees,
the first resistor being connected between a source of the first NMOS transistor and the ground terminal,
the second resistor being connected between a source of the second NMOS transistor and the ground terminal.

5. The constant current circuit according to claim 4,
wherein the first resistor has the same current direction as a current direction of the first NMOS transistor, and
wherein the second resistor has the same current direction as a current direction of the second NMOS transistor.

6. The constant current circuit according to claim 4,
wherein the first resistor has a current direction forming an angle of 90 degrees with a direction of current through the first NMOS transistor, and
wherein the second resistor has a current direction forming an angle of 90 degrees with a direction of current through the second NMOS transistor.

7. A semiconductor device comprising the constant current circuit of claim 1.

8. A semiconductor device comprising the constant current circuit of claim 4.
